(19) United States
(12) Patent Application Publication
(10) Pub. No.: US 2005/0242879 A1
(43) Pub. Date: Nov. 3, 2005

(54) Transmission arrangement and method for operating an amplifier in a transmission arrangement

(76) Inventor: Jan-Erik Muller, Ottobrunn (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/096,882

(22) Filed: Mar. 31, 2005

(30) Foreign Application Priority Data
Apr. 8, 2004 (DE) 10 2004 017 528.4

(51) Int. Cl. H03F 3/45

(52) U.S. Cl. 330/259

(57) ABSTRACT

A transmission arrangement includes a transmitter circuit for subjecting signals for transmission to signal conditioning, the signal output of said transmission arrangement being connected to a power amplifier. The power amplifier is produced in a semiconductor body and has at least one mode of operation that is characterized by at least one adjustable setting parameter. Outside of the semiconductor body, there is a programmable control circuit which is designed to send setting signals to the power amplifier in order to set the at least one adjustable setting parameter. The control circuit and the power amplifier are thus of separate design and can each be produced independently using the best technology.

### REFERENCE TO RELATED APPLICATIONS

This application claims the benefit of the priority date of German application DE 10 2004 017 528.4, filed on Apr. 8, 2004, the contents of which are herein incorporated by reference in its entirety.

### FIELD OF THE INVENTION

The invention relates to a transmission arrangement and a method for operating an amplifier in a transmission arrangement.

### BACKGROUND OF THE INVENTION

Transmission arrangements are used for applications in the field of communication within mobile communication appliances. In order to allow diverse applications in modern mobile communication appliances, it is necessary for the transmission unit to be able to cover a plurality of different modes of operation for different communication standards. Examples of different modes of operation are found in the various mobile radio standards, such as GSM/EDGE, GPRS, UMTS/WCDMA, 802.11a/b, GPS and others.

The various modes of operation differ, inter alia, in the output frequency of a transmission signal. A transmitter that covers the frequencies in a mobile communication appliance is referred to as having multiband capability. At the same time, different modulation types and output powers for the various communication standards need to be implemented in the transmission arrangement. This capability is called multimode capability. Another demand on modern transmitters in communication appliances is a low power requirement in order to increase the useful life in mobile communication appliances.

To date, a transmission arrangement of this type has been implemented in a mobile communication appliance by coupling a transceiver to one or more power amplifier paths connected in parallel. The power amplifier paths are in that case connected to one or more antennas. In this context, the transceiver in the transmission arrangement is used primarily for the signal conditioning for the signal that is to be transmitted. By way of example, the transceiver has an I/Q modulator that converts a complex-value baseband signal comprising an inphase component I and a quadrature component Q, to a signal with an intermediate frequency. In this case, the baseband signal carries the information that is to be transmitted. The signal converted to an intermediate frequency can now continue to be mixed onto the desired output frequency. Recently, however, “direct converters” are also used which convert the baseband signal to the output frequency directly without an intermediate frequency. Instead of an I/Q modulator, a polar modulator is also used whose input signals represent an amplitude and a polar angle. Since good RF small-signal properties are required in a transceiver, BiCMOS or RF-CMOS technologies are advantageously used.

Depending on the requirement in terms of frequency or mode of operation, the signal converted to the output frequency is supplied to one of the plurality of parallel-connected power amplifier paths, with the requirements in terms of frequency or operation being obtained from the mobile radio standard used. The transmission operation always involves selection of the respective power amplifier that can best amplify the signal for transmission on the basis of the mode of operation. The power amplifiers in the individual power amplifier paths should amplify the signal for transmission in accordance with the mobile radio standard used. Very good RF properties are therefore demanded for the power amplifiers. At the same time, a high withstand voltage and good current-carrying capacity are needed.

For this reason, the power amplifiers are often produced using separate semiconductor chips for the transceiver circuits. Preferably, power amplifiers are produced using GaAs, GaN, SiGe, SiC or InP semiconductors in this case. These semiconductor materials are distinguished primarily by high electron mobility and low power losses, which thus ensure good RF properties. To select the correct antenna or for the purpose of impedance matching, a switch unit or duplexer unit with an appropriate impedance matching circuit is usually connected between the output of the power amplifier and an antenna.

Besides the actual power amplifier circuits, bias or mode pilot circuits are also accommodated on the power amplifier's semiconductor chip. In this case, the bias and pilot circuits set the operating parameters for the power amplifier. By way of example, they prescribe the quiescent current for the amplifier, the supply voltage or the output power and perform alignment for a linear gain factor.

For reasons of circuitry, these bias circuits are frequently kept simple, which means that in multimode operation of the power amplifier it is necessary to accept compromises for the resultant properties. When expensive substrates such as GaAs or InP are chosen for the implementation, the bias or pilot circuit is thus also produced using expensive and complex technology. This increases the space requirement for a power amplifier. If the bias circuit fails then the entire chip is unfit, and if there is a change in the demand on the power amplifier then it is very frequently necessary to design and process a new bias and control circuit and hence a completely new power chip.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

The present invention is directed to a less expensive and more flexible transmission arrangement over conventional solutions, particularly for mobile radio applications. The invention is preferably intended to be able to be used equally for various modes of operation. The invention also includes a method that allows an amplifier in a transmission arrangement to be operated using simple means.

A transmission arrangement according to one embodiment of the invention comprises a transmitter circuit for subjecting transmission signals to signal conditioning.

The transmitter circuit contains a signal output. The transmission arrangement also contains at least one power amplifier produced in a semiconductor body. The power amplifier has at least one mode of operation, which is characterized by at least one adjustable parameter. The power amplifier contains a signal input and a signal output, and the signal input thereof is connected to the signal output of the transmitter circuit. In addition, the arrangement includes a programmable control circuit for the power amplifier. The programmable control circuit is produced outside of the semiconductor body and is designed to send setting signals to the power amplifier in order to set the at least one adjustable parameter. The semiconductor body comprises at least one measuring apparatus for measuring an operating parameter for the power amplifier. The measuring apparatus is coupled to the control circuit. The control circuit, for its part, is designed to set the at least one setting parameter on the basis of the measured operating parameter.

In one embodiment the invention contemplates producing the control circuit having the various signals for setting the power amplifier operational mode and the power amplifier in two different semiconductor bodies. This means that the power amplifier can be implemented using the best technology for the respective demand. The control circuit, which particularly contains the supply or bias circuits and the circuits for setting various modes of operation for the power amplifier, is implemented outside of the semiconductor body of the power amplifier and uses the technology that is best for it. The programmable control circuit can thus cover a plurality of modes of operation in the power amplifier in optimum fashion on account of the significantly more powerful digital and/or analog circuits that can be produced. The power amplifier can likewise be designed for a plurality of modes of operation which can be set by the control circuit, which means that it is possible to dispense with additional power amplifier trains in a transmission arrangement.

The measuring apparatus allows the best setting parameters to be produced for the various modes of operation of the power amplifier. In particular, it is also possible for the measuring apparatus to detect dynamic effects of the power amplifier in the course of operation and for these to be taken into account as appropriate when producing the setting parameters.

In one embodiment of the invention, the measuring apparatus in the semiconductor body is designed to measure a temperature rise caused by the power amplifier. In another embodiment of the invention, the measuring apparatus is designed to measure a drawn current in the power amplifier. Similarly, the measuring apparatus can measure the gain factor of the power amplifier or the power amplifier output power. The “standing-wave ratio” or the current or voltage amplitudes at the output of the power amplifier is/are also a possible operating parameter for the power amplifier which can be used to set the setting parameters. This allows the linearity of the amplifier to be kept constant, in one example.

The measuring apparatuses may also be arranged outside of the semiconductor body. This is expedient, inter alia, in the example of a sensor for measuring the standing wave ratio or the power which is output by the power amplifier.

In another embodiment of the invention, the setting parameter for the power amplifier (which setting parameter can be set by the control circuit) comprises the value of the quiescent current in the power amplifier. In addition, the setting parameter may also comprise a setting for the gain factor in the power amplifier or a setting for the output power in the power amplifier. Similarly, the control circuit can be designed to set a temperature dependency for the quiescent current. The term quiescent current includes, inter alia, the output quiescent current from the amplifier, but also an electrical variable that sets an operating point for the amplifier. In another embodiment, the control circuit comprises a detection device that evaluates the information transmitted by the measuring apparatuses. If a predetermined limit value is exceeded, the detection device is designed to output a signal for disconnecting the power amplifier. Preferably, the detection device thus forms a protective circuit that protects the power amplifier against overvoltage, excessively high current or a damaging standing-wave ratio.

In one example, the various setting parameters differ according to the mode of operation selected. In addition, the setting parameters can change as a function of time and also as a function of the mode of operation. In one embodiment, the measuring apparatus always sends the control circuit the up-to-date operating state of the power amplifier, and the control circuit then makes the optimum settings for the respective mode of operation and sends them to the power amplifier as setting parameters. Further setting parameters for the power amplifier, which the control circuit is designed to output, are parameters for the source impedance for the actuation, or parameters for dynamic gain control for producing a linear transfer characteristic for the power amplifier with simultaneously low drawn current in the entire modulation range. The control circuit or the semiconductor body can additionally contain a detection circuit for protecting the power amplifier in the event of overload.

In one embodiment, the power amplifier contains an inactive mode of operation in which no signal for transmission is amplified. In this mode of operation, the power amplifier needs to draw as little current as possible. The control circuit is thus designed to output the appropriate setting parameter for setting this inactive mode of operation. Depending on the demands on the setting parameters for the various modes of operation of the power amplifier, the control circuit is produced using CMOS technology or bipolar technology or using BiCMOS technology. The control circuit can be implemented in a second semiconductor body, and can preferably be produced using silicon technology. In another embodiment of the invention, the power amplifier is implemented in a semiconductor body which contains gallium arsenide or indium phosphide or silicon germanium compounds. Preferably, the power amplifier is produced using LDMOS (Laterally Doped MOS) technology or GaAs technology using MMIC (Monolithic Microwave Integrated Circuit) technology. These technologies are particularly suitable for circuits that have to have very good RF signal properties.

In another embodiment of the invention, the control apparatus contains a memory unit. This memory unit can store the setting parameters for the at least one mode of operation of the power amplifier. In addition, the control circuit may comprise an interface for programming the memory unit with the various setting parameters. In this case, the programming can be done using a digital interface or an analog interface. It is thus possible to combine various modes of operation of the power amplifier in the control device. Depending on the mode of operation, in one example, the necessary setting parameters are read from the memory unit, are processed further, and are transmitted to the power amplifier. It is particularly expedient in this example if the control circuit has a data input for setting the mode of operation.

A method for amplifying a signal comprises providing a power amplifier in a semiconductor body having at least one mode of operation for amplifying a transmission signal. In addition, a control circuit is provided outside of the semiconductor body of the power amplifier. A mode of operation that is characterized by at least one setting parameter is selected for the power amplifier. The at least one parameter for setting this mode of operation is transferred to the power amplifier by the control circuit. Preferably, this involves the control circuit being programmed with a number of different modes of operation characterized by setting parameters.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The text below gives a detailed explanation of the invention using exemplary embodiments with reference to the drawings, in which:

FIG. 1 shows a first exemplary embodiment of a transmission arrangement in a transmission path,

FIG. 2 shows a second exemplary embodiment of an inventive transmission arrangement in an execution path, and

FIG. 3 shows a detail from a transmission arrangement based on one embodiment of the invention.

### DETAILED DESCRIPTION OF THE INVENTION

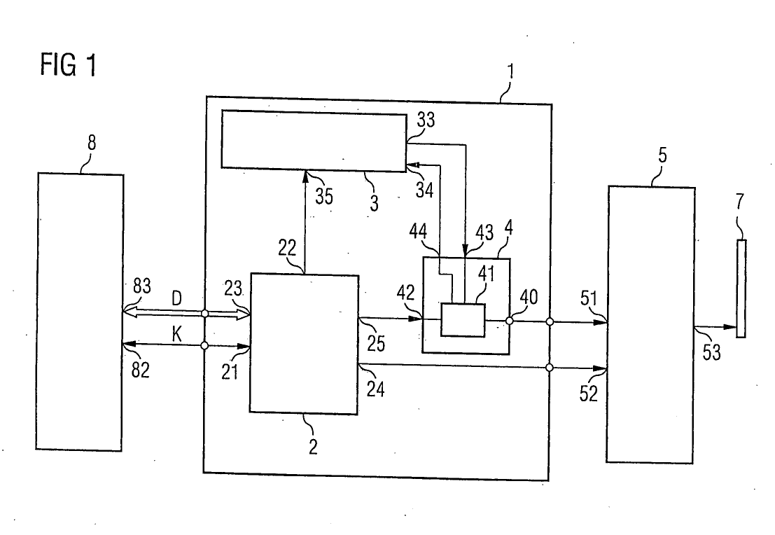

FIG. 1 shows an inventive transmission arrangement 1 in a transmission path. The transmission path is part of a mobile communication appliance (not shown for reasons of clarity) that can send and receive in accordance with a plurality of mobile radio standards. The mobile radio standards make different demands on the transmission path. Whereas, by way of example, the GSM mobile radio standard involves a signal for transmission always being transmitted with the same amplitude during the transmission operation, the signal for transmission is amplitude-dependent in the WCDMA mobile radio standard. The demands regarding linearity of the gain of a power amplifier in the transmission path are therefore significantly higher.

Besides the inventive transmission arrangement 1, the transmission path also contains a baseband unit 8. The baseband unit 8 has an output 83 for a data stream D, which is connected to an input 23 on a transmitter circuit 2 in the inventive transmission arrangement 1. The output 82 for a control data stream K is connected to an input 21 on the transmitter circuit 2. The baseband unit 8 produces the signal for transmission in the form of a digital data stream D. The digital data stream D has already been modulated using a modulation type provided for the chosen mobile radio standard. Preferably, vector modulation with different modulation types is used for the various communication standards. In the case of vector modulation, the baseband unit 8 produces a complex, digital baseband signal having an inphase component I and a quadrature component Q. The two components I and Q produce the digital data stream D. In addition, the baseband unit 8 uses a pilot current to send preferably digital control signals K to the transmitter circuit 2 in the inventive transmission arrangement. The control signals K are used to set the maximum power for transmission, filters, transmission frequency and further parameters. Depending on the pilot current K, the transmitter circuit 2 makes the necessary settings for the signal for transmission.

The transmitter circuit 2 also has a control output 22 that is connected to a control input 35 on a bias and control circuit 3. The transmitter circuit 2 also has a signal output 25 and a further control output 24. The control output 24 is connected to a control input 52 on a duplexer unit 5. The signal output 25 is connected to an input 42 on a power amplifier 41.

The power amplifier 41 is implemented in a semiconductor body 4 or in a chip 4. It thus forms an integrated circuit in this chip. All of the inputs and outputs on the power amplifier 41 are formed by connections on the surface of the semiconductor body 4. The power amplifier 41 has a signal output for the amplified signal for transmission, said signal output being connected to an input 51 on the duplexer unit 5. The duplexer unit 5 contains a matching network (not shown here for reasons of clarity) that matches the impedance of the output 40 of the amplification device 41 to that of the antenna 7 connected to the output 53. This reduces the power reflected by the antenna 7 and reduces the standing-wave ratio between the output 40 of the power amplifier 4 and the antenna 7. In this case, the matching network chosen is dependent on the transmission frequency of the signal for transmission. In addition, the duplexer unit 5 may also have additional resonant circuits for matching the resonant frequency of the antenna 7 to the transmission frequency.

The power amplifier 41 also has an input 43 for supplying setting, bias or control signals. The input 43 is connected to an output 33 on the bias or control circuit 3. In this case, the input 43 and the output 33 comprise a plurality of connections and parallel-connected lines. In one embodiment, the setting signals are analog signals and are transmitted on the respective lines, and are used to set parameters for the power amplifier 41 which thus allow optimum amplification of the signal for transmission for a specific mode of operation. The setting signals are thus used directly for setting parameters for the power amplifier 41 in the semiconductor body 4. The settings made at the setting input 43 using the signals relate, inter alia, to the quiescent current drawn by the amplifier, to the amplifier's gain factor, supply voltage and to the output impedance of the amplifier. The maximum output power is also determined. In addition, further lines in this embodiment provide the supply voltage and the supply current for the power amplifier.

There are also a plurality of measuring apparatuses which ascertain various types of operating parameter for the power amplifier 41 in the course of operation. In this case, some measuring apparatuses are implemented within the semiconductor body 4. Further measuring apparatuses are connected to the inputs and outputs outside of the semiconductor body. The data ascertained by the measuring apparatuses are produced at an output 44 of the semiconductor body 4, which is connected to an input 34 on the control circuit 3.

The control circuit 3 is designed to produce and send the setting parameters to the output 33. To this end, the control circuit 3 first receives a signal from the transceiver 2 via the input 35, which tells it the mode of operation of the power amplifier for the signal that is to be transmitted and amplified. From this information, the control circuit 3 produces all of the setting parameters for this mode of operation. These are transmitted to the power amplifier and thus set the power amplifier 41 in optimum fashion for this mode of operation.

If the operating parameters for the power amplifier 41, for example its temperature, its drawn current, the standing-wave ratio at the output 40 or else its gain factor, change in the course of operation, this is registered by the measuring apparatuses. These produce a signal and send it to the output 44. The measured signals are received at the data input 34 of the control circuit 3 and are processed further. From these, the control circuit derives changed setting parameters, which are supplied to the power amplifier 41 in the semiconductor body 4 again at the output 33. The setting parameters are thus changed as appropriate in order to match themselves to the new operating conditions of the power amplifier 41. The process takes place dynamically and continuously, which means that it is always certain that the power amplifier is operating in optimum fashion. In this case, the bias or control circuit 3 is decoupled from RF interference radiation, in particular. The direct supply lines are also decoupled well in this way from RF interference in the power amplifier.

If a new mode of operation is required, for example on account of a new mobile radio standard, the baseband unit 8 indicates this to the transceiver in the transmission arrangement 1 using the control signals K at its output 82. From this, the transceiver ascertains the required mode of operation for the power amplifier 41 and sends an appropriate setting signal via its setting output 22 to the control circuit 3. The control circuit 3 produces the new setting parameters for the power amplifier 41 which are required for this mode of operation. By way of example, this may be a new gain control, a new linearity profile or else temperature compensation for the quiescent current.

If there is a change, by way of example, from a mode of operation in the power amplifier 41 in which signals with constant amplitude are amplified to a mode of operation in which amplitude-dependent signals need to be amplified, then the control circuit 3 needs to choose the setting parameters such that the power amplifier amplifies the signal with as little distortion as possible. At the same time, the transceiver 2 uses the control output 24 to switch the duplexer unit to a new frequency band or changes the matching network in the duplexer unit 5 in order to achieve optimum matching to the output of the power amplifier 41.

The power amplifier 41 in the transmission arrangement based on the invention can now be designed to be as broadband as possible. The necessary bias, control and pilot settings are made by the control circuit using the setting parameters. The broadband implementation of the power amplifier and the logical transfer of all bias or pilot circuits to a programmable control circuit make it possible to dispense in part with additional amplifier trains connected in parallel. The separately implemented control circuit 3 is now independent of temperature and can be designed and produced independently of the power amplifier. Its flexible programming also makes it possible to produce new modes of operation for different signals with the same power amplifier 41. RF decoupling between the bias and the control circuit and the RF power amplifier is improved.

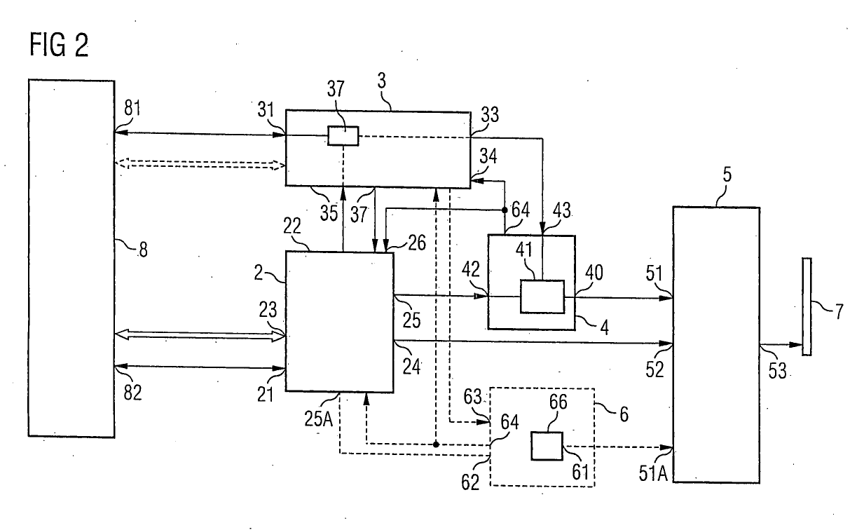

The exemplary embodiment in FIG. 2 shows another aspect of the invention. In this example, identical components bear identical reference symbols. Besides the control input 35, the control circuit 3 in this case contains a further control input 31 which is connected to an output 81 on the baseband unit 8. This output can be used to transmit further information to the control circuit 3. In the exemplary embodiment, the input 31 is in the form, inter alia, of a programming input for a memory unit 37. The memory unit 37 stores setting parameters for various modes of operation of the power amplifier 41. The communication between the baseband unit 8 and the bias or control circuit 3 and the transmitter circuit 2 and the bias or control circuit 3 takes place via a digital “three-wire bus”. If a signal for setting a mode of operation is received, the control circuit 3 takes the setting parameters for the mode of operation which is to be set from its memory unit 37. By way of example, these may be additional amplitude information for the signals for transmission, or signals for altering the output power of the amplifier 41. The control circuit 3 can thus also acknowledge important operating information to the transceiver 2 or to the baseband unit 8 via the three-wire bus.

In addition, the input of the bias or control circuit 3 is used for dynamically notifying it of a change in the signals for transmission. By way of example, the input 31 is used to transmit the crest factor for the signal that is to be transmitted or the maximum amplitude. The bias or control circuit 3 can thus react to the future signals and can adjust the power amplifier accordingly. Distortion on account of excessive input amplitudes is thus prevented. The additional input 31 therefore permits dynamic and very rapid adjustment to suit the signals for transmission that are changing in the course of operation. The setting signals at the second input that are transmitted by the baseband unit can thus be used advantageously for fine-tuning the setting parameters.

In this embodiment, the transmitter circuit 2 additionally has a data input 26 for supplying measurement results to the measuring apparatuses in the semiconductor body 4. Using this operating information from the power amplifier 41, the transceiver can make settings in its circuits so as to achieve even better gain for the signal that is to be transmitted. By way of example, suitable measures can thus be used to reduce distortions in the signal for transmission.

In addition, this exemplary embodiment of the inventive transmission arrangement contains a further parallel-connected amplifier train 66, represented by the dashed lines. The second amplifier train 66 is implemented in a dedicated semiconductor body 6 and likewise comprises one or more power amplifiers and measuring apparatuses. The output 61 of the amplifier train 66 is likewise connected to a further input 51A on the duplexer unit 5. A further signal output 25A on the transmitter circuit 2 is connected to an input 62 on the power amplifier train 66. The latter's setting parameters for setting the mode of operation are received by the second power amplifier train 66 from the control circuit 3 via said power amplifier train's setting input 63. Measuring apparatuses in the semiconductor body 6 of the power amplifier train 66 transmit the operating information and operating parameters to the control circuit 3 or to the transmitter circuit 2.

A second parallel-connected power amplifier train of this type may be necessary when not all possible modes of operation can be covered by one power amplifier. Alternatively, a second amplifier may be necessary if the transceiver 2 is designed for a higher output power or if a higher gain is not necessary. The second power amplifier 66 now comprises just a single output stage. This is designed using expensive and complex technology in a GaAs or InP semiconductor with outstanding radio-frequency properties. Depending on the mode of operation, the second power amplifier 6 is used whenever the transceiver 2 is already outputting the signal for transmission with its full modulation range.

The outputs 61 and 40 of the semiconductor bodies 6 and 4 each have an impedance matching circuit connected upstream of them which can be controlled using the signals from the control device 3. The control circuit sets the output impedance using the parameters measured by the measuring apparatuses such that the output of the semiconductor bodies is matched to the respective inputs of the duplexer.

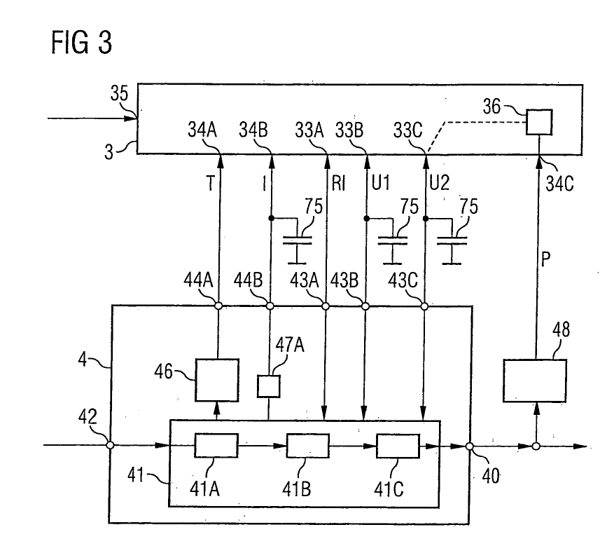

FIG. 3 shows a detail of one exemplary transmission arrangement 1 from FIG. 1. The power amplifier 41 is integrated in a semiconductor body 4 and comprises three individual amplifier stages 41A, 41B and 41C connected in series with one another. The amplifier stages can just as well be connected in parallel, however. The individual amplifier stages 41A to 41C are produced in a monolithic structure within the semiconductor body 4 and are in the form of integrated circuits. Preferably, the semiconductor body comprises a material that has outstanding radio-frequency properties. By way of example, one semiconductor material is gallium arsenide GaAs, which is distinguished by very high electron mobility. Other examples are indium phosphide InP or silicon germanium SiGe. The semiconductor body 4 accommodates a plurality of measurement sensors 46 and 47 connected to the amplification device 41.

By way of example a temperature measurement sensor 46 monitors the temperature rise in the semiconductor body 4. A temperature rise is caused by heat losses from the actual power amplifier circuits 41A to 41C when amplifying a signal. A change of temperature in the amplifier circuits in turn alters other electrical parameters, such as resistance, power consumption or reactances. Depending on the temperature T, the setting parameters therefore need to be chosen in appropriate fashion. The measurement sensor thus transmits the measured temperature T or the change in the temperature to the measurement input 34A of the bias or control circuit 3.

In addition, there is a measurement sensor 47A. In this exemplary embodiment, this is likewise accommodated within the semiconductor body 4 of the power amplifier 41 and ascertains the drawn current I in the amplifier train 41. The measurement result is transmitted to a second measurement input 34B via the connection 44B on the surface of the semiconductor body 4.

Finally, the output 40 of the amplifier train 41 in the semiconductor body 4 has a measurement circuit 48 connected downstream of it which determines the standing-wave ratio VSWR. The standing-wave ratio indicates the ratio between radiated and reflected power. This measured value is particularly important for protecting amplifiers against damage that arises where there is excessive reflected power. In addition, the measured value for the standing-wave ratio can be used to optimize the linearity of the power amplifier. The standing-wave ratio VSWR is sent to a third measurement input 34C.

Together with the setting signal at the input 35, which signal communicates the mode of operation for the power amplifier to the control circuit 3, the bias or control circuit 3 takes the transmitted measurement results and produces a plurality of setting parameters dynamically. In the present exemplary embodiment, these are the quiescent current RI and the voltages U1 and U2. These are sent to the outputs 33A to 33C and are supplied to the amplifier train 41 in the semiconductor body 4. To decouple from reflected RF radiated interference, a decoupling means 75 is provided, as indicated. The continuous transmission of the measurement results by the measuring apparatuses 46, 47 and 48 dynamically adjusts the setting parameters I, U1 and U2. The power amplifier train 41 with its individual power amplifier stages 41A to 41C is thus, in one example, always actuated in optimum fashion.

At the same time, the bias or control circuit contains a detection and protection device 36. This evaluates the standing-wave ratio VSWR at the input 34C. If a limit value is exceeded, it reduces the voltage U2 as indicated so as to protect the power amplifier 41 in the semiconductor body 4 against damage. By way of example, it can also open a switch or can disconnect the amplifier completely. In this embodiment, the protective apparatus 36 evaluates only the standing-wave ratio. However, it is also possible to observe further operating parameters for protection against overload or damage. In addition, the standing-wave ratio can be used to set various parameters, such as impedance matching.

The logical separation of the bias or control circuit in the control circuit 3 and the actual power amplifier train within a separately arranged semiconductor body means that flexible and simple assembly is still ensured. Thus, by way of example, the control circuit 3 and the power amplifier 41 in the inventive transmission arrangement can be implemented in individual chips that are assembled using flip-chip or face-to-face technology. This technology additionally allows simple placement of various measurement sensors within and outside of the semiconductor body for the power amplifier. Any space taken up thus remains approximately constant, but the expensive technology for producing the power amplifier is not needed for the bias or control circuit. This results in greater flexibility and precision for the bias settings.

The logical separation (shown here) in the transmission arrangement can also be produced in the same way for a corresponding reception path. In this case, it is possible to separate the bias and control circuit in a reception amplifier and the actual reception amplifier train, for example. The two logic circuit blocks, control and bias circuit on the one hand and the actual amplifier train on the other, are implemented separately in the respective optimum technologies using the optimum materials. This significantly increases flexibility.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A transmission arrangement, comprising:
a transmitter circuit configured to provide signal conditioning on transmission signals and provide such signals at a signal output thereof;
at least one power amplifier, formed in a semiconductor body, with a signal input coupled to the signal output of the transmitter circuit, and having a signal output and a setting input configured to set one of a plurality of possible modes of operation for the power amplifier based on at least one setting parameter applied to the setting input;
a programmable control circuit, produced outside of the semiconductor body, and configured to provide the at least one setting parameter to the setting input of the power amplifier, wherein the control circuit comprises a memory unit configured to store setting parameters for at least one of the plurality of modes of operation of the power amplifier, the control circuit further comprising an interface or input for programming the memory unit with the setting parameters;
the semiconductor body comprising at least one measuring apparatus configured to measure an operating parameter associated with the power amplifier, wherein the measuring apparatus is coupled to the control circuit, and wherein the control circuit is configured to output the at least one setting parameter based on the measured operating parameter.

2. The transmission arrangement of claim 1, further comprising another measuring apparatus provided outside of the semiconductor body, and configured to measure an operating parameter associated with the power amplifier, wherein another measuring apparatus is coupled to the control circuit, and wherein the control circuit is configured to output the at least one setting parameter based on the measured operating parameter from the another measuring apparatus.

3. The transmission arrangement of claim 1, wherein the control circuit interface is further configured to supply one or more dynamic tuning signals, and wherein the control circuit is configured to output the at least one setting parameter based on the supplied one or more tuning signals, wherein the one or more tuning signals are a function of the transmission signal that is to be amplified by the power amplifier.

4. The transmission arrangement of claim 1, wherein the interface is configured to supply a digital program data stream for programming the memory unit.

5. The transmission arrangement of claim 1, wherein the transmitter circuit is further configured to send a signal to a data input of the control circuit in order to set the mode of operation of the power amplifier.

6. The transmission arrangement of claim 1, wherein the measuring apparatus is configured to measure a temperature or a temperature change in the semiconductor body or in the power amplifier.

7. The transmission arrangement of claim 1, wherein the measuring apparatus is configured to measure a drawn current or current consumption in the power amplifier.

8. The transmission arrangement of claim 1, wherein the measuring apparatus is configured to measure a gain factor or an output power for the power amplifier.

9. The transmission arrangement of claim 2, wherein the another measuring apparatus is coupled to the output of the power amplifier and is configured to measure a standing-wave ratio, and provide the standing-wave ratio to the control circuit.

10. The transmission arrangement of claim 1, wherein the setting parameter for the power amplifier comprises a value of the quiescent current in the power amplifier.

11. The transmission arrangement of claim 1, wherein the setting parameter for the power amplifier comprises a gain factor setting in the power amplifier, or an output power setting in the power amplifier.

12. The transmission arrangement of claim 1, wherein the control circuit is further configured to set a particular temperature dependency for the quiescent current in the power amplifier.

13. The transmission arrangement of claim 1, wherein the at least one mode of operation of the power amplifier comprises an inactive mode of operation, wherein the control circuit is configured to output a setting parameter for setting the inactive mode of operation.

14. A method for operating a power amplifier in a transmission arrangement, comprising:
providing a power amplifier in a semiconductor body having at least one mode of operation, configured to amplify a transmission signal;
providing a control circuit outside of the semiconductor body; and
choosing a mode of operation for the power amplifier using least one setting parameter,
wherein the at least one setting parameter is transferred to the power amplifier by the control circuit.

15. The method of claim 14, wherein the step of providing the control circuit comprises programming the control circuit with a number of different modes of operation for the power amplifier.

16. The method of claim 14, wherein choosing the mode of operation comprises:
ascertaining an operating parameter for the power amplifier using a measuring apparatus in the semiconductor body of the power amplifier; and
producing a setting parameter which is optimum for the chosen mode of operation on the basis of the ascertained operating parameter.

17. A transmission system, comprising:
a transceiver configured to output transmission data in a transmission signal;
a control circuit formed on a first semiconductor body, and configured to ascertain an operation mode from the transceiver and output one or more setting parameters based thereon; and
a power amplifier circuit formed on a second semiconductor body different than the first semiconductor body, and configured to generate an amplified transmission signal based on the transmission signal and the one or more setting parameters.

18. The transmission system of claim 17, wherein the control circuit is further configured to vary the one or more setting parameters based on measurement data associated with an operation of the power amplifier circuit.

19. The transmission system of claim 17, further comprising a duplexer unit operably coupled to the power amplifier circuit and the transceiver, and configured to selectively couple one of a plurality of impedance matching networks to an output of the power amplifier based upon a control signal from the transceiver that is indicative of an operational mode of the transmission system.

20. The transmission system of claim 17, wherein the transceiver is further configured to provide signal conditioning to an incoming transmission signal and provide the conditioned transmission signal to the power amplifier, and further configured to receive a control data signal, generate an operational mode control signal in response thereto, and transmit the operational mode control signal to the control circuit.
